(19) United States
(12) Patent Application Publication
(10) Pub. No.: US 2010/0062185 A1
(43) Pub. Date: Mar. 11, 2010

(54) METHOD FOR PLATING FILM ON A TRANSMISSION MECHANISM

(76) Inventor: YU-HSUEH LIN, TAIPEI CITY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/352,737

(22) Filed: Jan. 13, 2009

(30) Foreign Application Priority Data
Sep. 5, 2008 (TW) 097134050

(51) Int. Cl. C23C 16/44

(52) U.S. Cl. 427/585

(57) ABSTRACT

A method for plating films on a transmission mechanism includes the steps of: cleaning the transmission mechanism; injecting hydrogen and tetra-methylsilane gases and applying an electric current to generate a bias electric field within a working chamber, thereby forming an adherent film on the transmission mechanism; injecting hydrocarbon gas together with the hydrogen and tetra-methylsilane gases into the working chamber, thereby forming a mixed film on the adherent film; and injecting the hydrogen and tetra-methylsilane gases together with hydrocarbon gas into the working chamber while maintaining the bias electric field at 400-700 V and the applied electric current at 800-1500 watt, thereby forming a noncrystalline DLC film on the mixed film.

This application claims the benefit of the Taiwan Patent Application Serial NO. 097134050, filed on Sep. 5, 2008, the subject matter of which is incorporated herein by reference.

### BACKGROUND OF THE INVENTION

1. Field of the Invention

The present invention relates to a fabrication technology for a transmission mechanism, more particularly to a method for plating films on an external surface of the transmission mechanism.

2. Description of the Prior Art

In a driving device, a transmission mechanism is implemented to transfer a driving force in order to drive an article. The transmission mechanism generally includes wheels, drive shafts, bearing units, racks and pinion assembly, helical rods and gear assemblies and engagement or contact among these elements may result in friction. In case the friction, resulting from sliding contact of the elements, reaches a specific amount, may cause unstable driving of the article. If severe, the conventional transmission mechanism is unable to perform its task effectively.

According to the prior art technology, a noncrystalline DLC (diamond-like carbon) film is usually coated on an external surface of the conventional transmission mechanism in order to provide a longer service life thereof. The noncrystalline DLC (diamond-like carbon) film structure is caused due to densely depositing carbon and hydrogen on the transmission mechanism and therefore includes more sp2 hybridized orbital than sp3 hybridized orbital. The characteristic of the noncrystalline DLC material is very similar to a natural diamond, and has high hardness, thermal resistant and anti-corrosion properties. Therefore, when the external surface of the transmission mechanism is coated with a noncrystalline DLC film, the transmission mechanism becomes thermal-and-wear resistant in addition to the high hardness property.

The external surface of a conventional transmission mechanism is usually heat-treated and is mostly made of steel in order to possess the high hardness. Moreover, the noncrystalline DLC material has a relatively high hardness so that the problem of insufficient adhesive force exists. Increase in the thickness of the noncrystalline DLC film consequently results in enhancement of intrinsic tensile stress. The noncrystalline DLC film will be ruptured and falls of the transmission mechanism when the tensile stress is too large. Due to the aforesaid reason, the noncrystalline DLC film on the transmission mechanism is fabricated to have relatively small thickness to prevent rupture and falls off the mechanism. Small thickness in the noncrystalline DLC film reduces the heat-and-wear resistance abilities thereof.

A new film plating technology has been proposed in the following to compare with the preceding ones. FIG. 1 shows a perspective view of a conventional transmission mechanism 1 to include a plated barrel unit 11 and a plated driven shaft 12.

The barrel unit 11 includes a barrel housing 111, a drive shaft 112 received rotatably in the barrel housing 111, and a bearing unit 113 sandwiched between the drive shaft 112 and the housing 111 to permit smooth rotation of the drive shaft 112. The barrel housing 111 has an extension plate formed with two mounting holes 1111, 1112 to facilitate securing the housing stationarily thereat. The driven shaft 12 is connected securely or is integrally and coaxially formed with the drive shaft 112 so as to be driven thereby, and has a belt groove. A force transmission belt 2 is trained over the groove in the driven shaft 12.

During the force transmission operation, different frictions are resulted between the driven shaft 12 and the transmission belt 2, the drive shaft 112 and the bearing unit 113, and the bearing unit 113 and the barrel housing 111. The longer the transmission operation proceeds, the larger the friction becomes among the elements. The friction at certain degree will result in unstable rotation of the driven shaft 12 within the housing 111. The force transmission operation cannot be performed if the friction is tremendously large.

For the aforesaid transmission mechanism (the barrel unit 11 and the driven shaft 12) to possess high wear-resistance, fine adhesive force should be present between the noncrystalline DLC film and the transmission mechanism. Then only, the barrel unit 11 and the driven shaft 12 will be coated with the noncrystalline DLC films, respectively. The following is an example illustrating the technology how the noncrystalline DLC film is formed on the barrel unit 11 and the driven shaft 12 respectively.

FIG. 2 shows a cross-sectional view of the driven shaft 12 taken along lines A-A in FIG. 1. The driven shaft 12 includes a main axle 121, upon which an adherent film 122 and a noncrystalline DLC film 123 are formed by a PECVD (plasma enhanced chemical vapor deposition) apparatus in a working chamber.

For forming the adherent film, the main axle 121 is disposed firstly within the working chamber. The air within the working chamber is pumped out so as to maintain the working chamber under 0.1-0.5 torr. The working chamber is heated simultaneously so that the temperature of the working chamber is maintained above 200° C. Later, after applying an electric current with a power of 100 W (watt), argon gas is injected into the working chamber, where plasma-like argon ions are obtained after the ionization process. Afterward, Methane (CH₄) and Silane (SiH₄) gases are respectively injected into the working chamber, wherein flow rate of argon is 80 ml/min; flow rate of Methane is raised gradually from 0 ml/min to 60 ml/min while flow rate of Silane is gradually decreased from 3 ml/min to 0 ml/min. The working chamber is maintained under the same situation for 36 minutes so as to deposit the chemical compound of Si, SiC and Argon and a minor portion of hydrocarbon, thereby forming the adherent film 122 on outer surface of the main axle 121.

For fabricating the noncrystalline DLC film, two methods can be implemented. The first method provides the noncrystalline DLC film with a high purity of DLC. The second method provides the noncrystalline DLC film having silicon amount higher than the previous ones.

According to the first method, the working chamber is heated so that the temperature rises above 200° C. Later, argon and methane gases are injected while maintaining the pressure of the working chamber roughly at 0.3 torr. An electric current with a power of 100 W is applied on the working chamber, wherein flow rate of argon is about 80 ml/min while flow rate of methane is 60 ml/min. The working chamber is maintained under the same situation for 60 minutes, thereby forming the noncrystalline DLC film 123 having higher purity of DLC.

According to the second method, the working chamber is heated so that the temperature rises above 200° C. Later, argon, methane and silane gases are injected while maintaining the pressure of the working chamber roughly at 0.3 torr. An electric current with a power of 100 W is applied on the working chamber, wherein flow rate of argon is about 80 ml/min, flow rate of methane is 60 ml/min while flow rate of Silane is 2 ml/min. The working chamber is maintained under the same situation for 60 minutes, thereby forming the noncrystalline DLC film 123 having silicon amount higher than the film produced in accordance with the first method.

For those persons skilled in the art, the following severe problems still exist no matter which method is selected for forming the noncrystalline DLC film 123.

Firstly, when forming the adherent film 122 and the noncrystalline DLC film 123, the temperature of the working chamber is raised above 200° C. Under this temperature, the main axle 121 made from metal may encounter thermal cycling effect, thereby reducing hardness of the external surface of the main axle 121. When the adherent film 122 and the noncrystalline DLC film 123 are coated successively on the main axle 121 so as to form the plated driven shaft 12, the entire hardness of the latter will decline, thereby lowering the wear-resistant ability thereof.

Secondly, when forming the adherent film 122 and the noncrystalline DLC film 123, argon gas is required to be injected into the working chamber. Thus, the adherent film 122 and the noncrystalline DLC film 123 formed accordingly possess argon compound. Covalent bond is mainly used for bonding in the noncrystalline DLC film 123, but it is not so in the argon compound. It is apparent that covalent bond and the bonding ability in the noncrystalline DLC film 123 are subjected to be ruptured due to presence of the argon compound, thereby lowering hardness of the external surface the noncrystalline DLC film 123, which, in turn, reduces the wear-resistant ability of the plated driven shaft 12.

Due to aforesaid facts, it is urgently needed to invent a new method for plating film on the external surface of a transmission mechanism in order to overcome the problems encountered during use of the prior art plating method for transmission mechanism.

### SUMMARY OF THE INVENTION

The object of the present invention is to provide a plating method for a transmission mechanism, in which, the effect of thermal cycling, rupture of the bonding ability in the noncrystalline DLC film due to presence of argon compound, lowering in the wear-resistance of the noncrystalline DLC film encountered in the prior art are overcome.

A method for plating films on the external surface of a transmission mechanism is provided according to the present invention. The method accordingly includes the steps of: (a) preparing the transmission mechanism; (b) cleaning the external surface of the transmission mechanism; (c) disposing the transmission mechanism into a working chamber, injecting hydrogen and tetra-methylsilane [TMS;Si(CH₃)₄] gases therein and applying an electric current to generate a bias electric field within the working chamber, thereby forming an adherent film on the external surface of the transmission mechanism; (d) injecting hydrocarbon gas together with the hydrogen and tetra-methylisilane gases into the working chamber, thereby forming a mixed film on an external surface of the adherent film, wherein the mixed film consisting of noncrystalline DLC (diamond-like carbon) material and composition of the adherent film, the mixed film having a distal portion that is spaced farthermost from the transmission mechanism and that consists of larger noncrystalline DLC (diamond-like carbon) material when compared to the remaining portion of the mixed film; and (e) injecting the hydrogen and tetra-methylsilane gases together with hydrocarbon gas into the working chamber, thereby forming a noncrystalline DLC film on the mixed film.

According to the present invention, during plating process of the noncrystalline DLC film, the temperature in the working chamber is maintained below 100° C. and the power of the applied current is raised to 800-1500 W. Therefore, argon gas is not required to be injected into the working chamber to maintain the plasma-like status in the working chamber.

When compare to the prior art method, the temperature in the working chamber is maintained below 100° C. according to the present method to avoid the problem of thermal cycling effect, thereby providing the external surface of the transmission mechanism to possess a relatively high hardness. In addition, during formation of the adherent film, the mixed film and the noncrystalline DLC film, argon gas is not required to be injected into the working chamber. Thus, argon compound is excluded from the films formed according to the present method.

### BRIEF DESCRIPTION OF THE DRAWINGS

Other features and advantages of this invention will become more apparent in the following detailed description of the preferred embodiment of this invention, with reference to the accompanying drawings, in which:

FIG. 1 is a perspective view of a conventional transmission mechanism;

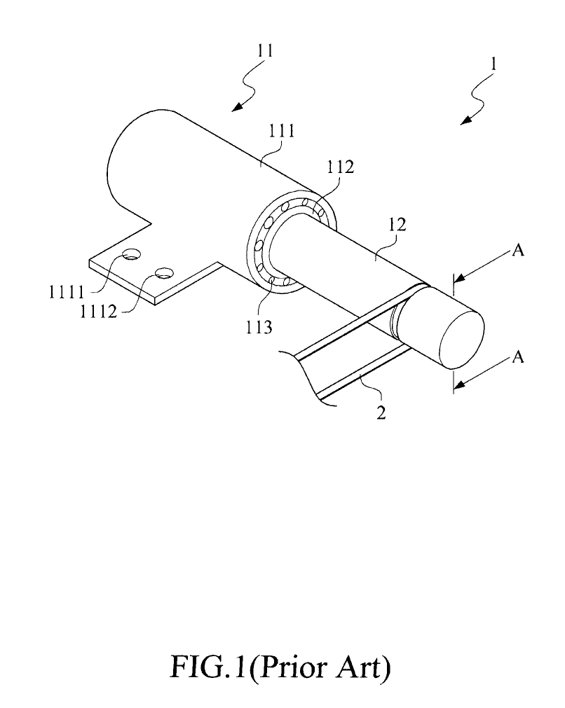

FIG. 2 is a cross-section view of a driven shaft of the conventional transmission mechanism taken along lines A-A in FIG. 1;

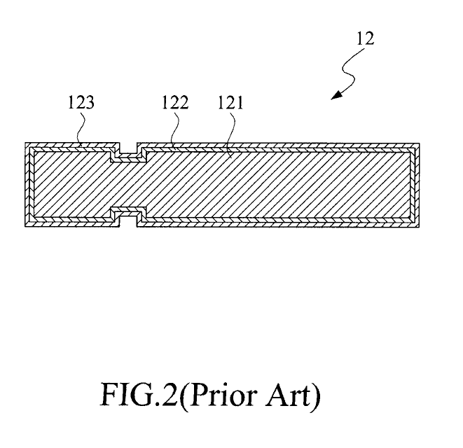

FIG. 3 is a perspective view of a transmission mechanism for undergoing in the film plating method of the present invention;

FIG. 4 is a cross-section view of a driven shaft of the transmission mechanism shown in FIG. 3 and taken along lines B-B;

FIG. 5 illustrates a plasma enhanced chemical vapor deposition apparatus for conducting the film-plating method of the present invention;

FIG. 6 illustrates how the driven shaft of the transmission mechanism is mounted in the working chamber for conducting the method of the present invention;

FIG. 7 illustrates gas being injected into an electric field within the working chamber during carrying out the method of the present invention;

FIG. 8 shows an adherent film being plated on the driven shaft of the transmission mechanism according to the method of the present invention;

FIG. 9 is an enlarged view of the encircled portion shown in FIG. 8;

FIG. 10 illustrates how a mixed film being plated on the adherent film on the driven shaft of the transmission mechanism according to the method of the present invention;

FIG. 11 is an enlarged view of the encircled portion shown in FIG. 10; and

FIG. 12 illustrates how a noncrystalline DLC film being plated over the mixed film on the driven shaft of the transmission mechanism according to the method of the present invention.

### DETAILED DESCRIPTION OF THE PREFERRED EMBODIMENT

The method of the present invention is used for plating films on the external surface of a transmission mechanism including a bearing unit, a drive shaft, a chain, a gear wheel, a rack, a cam member, a bevel shaft or a combination thereof.

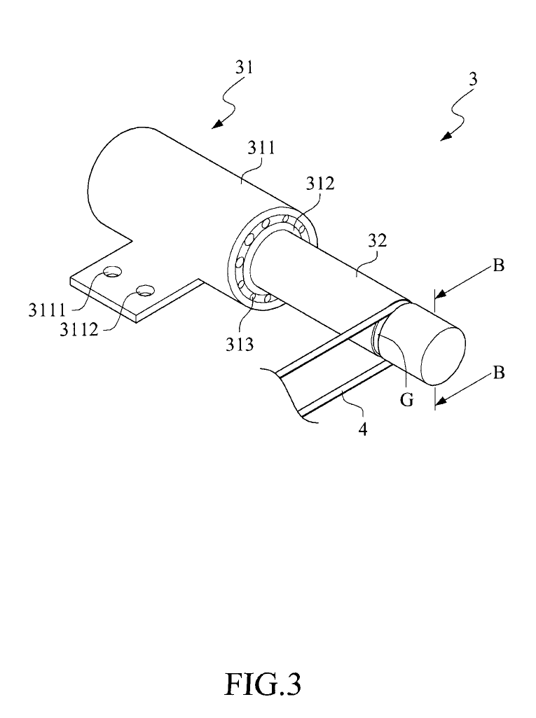

FIG. 3 is a perspective view of the transmission mechanism 3 for undergoing in the film plating method of the present invention. The transmission mechanism 3 accordingly includes a plated barrel unit 31 and a plated driven shaft 32.

The barrel unit 31 includes a barrel housing 311, a drive shaft 312 received rotatably in the barrel housing 311, and a bearing unit 313 sandwiched between the drive shaft 312 and the barrel housing 311 to permit smooth rotation of the drive shaft 312. The barrel housing 311 has an extension plate formed with two mounting holes 3111, 3112 to facilitate securing the housing stationarily thereat. The driven shaft 32 is connected securely or is integrally and coaxially formed with the drive shaft 312 so as to be driven thereby, and has a belt groove G. A force transmission belt 4 is trained over the groove G in the driven shaft 32. One end of the driven shaft 32 can be connected to a motor while the other end can be connected to a fan unit or any other driven object.

During the force transmission operation, different frictions and wearing are resulted between the driven shaft 32 and the transmission belt 4, the drive shaft 312 and the bearing unit 313, and the bearing unit 313 and the barrel housing 311. The longer the transmission operation proceeds, the larger the friction becomes among the elements. In a light condition, the friction at certain degree will provide unstable transmission force. In a severe condition, the force transmission operation cannot be performed if the friction is tremendously large.

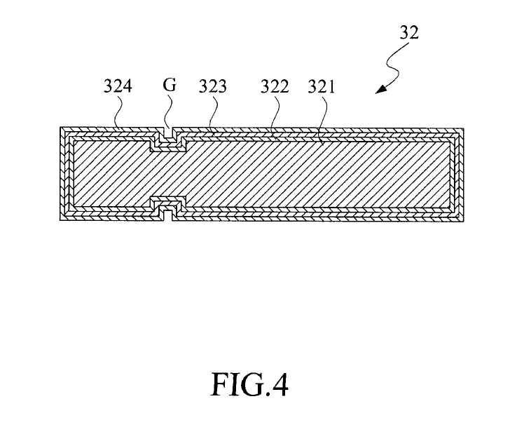

In order to better understanding of the present method, one embodiment is illustrated in the following paragraphs, wherein FIG. 4 is a cross-section view of a driven shaft of the transmission mechanism and taken along lines B-B in FIG. 3. As illustrated, the driven shaft 32 includes a main axle 321, upon which an adherent film 322, a mixed film 323 and a noncrystalline DLC film 324 123 are formed.

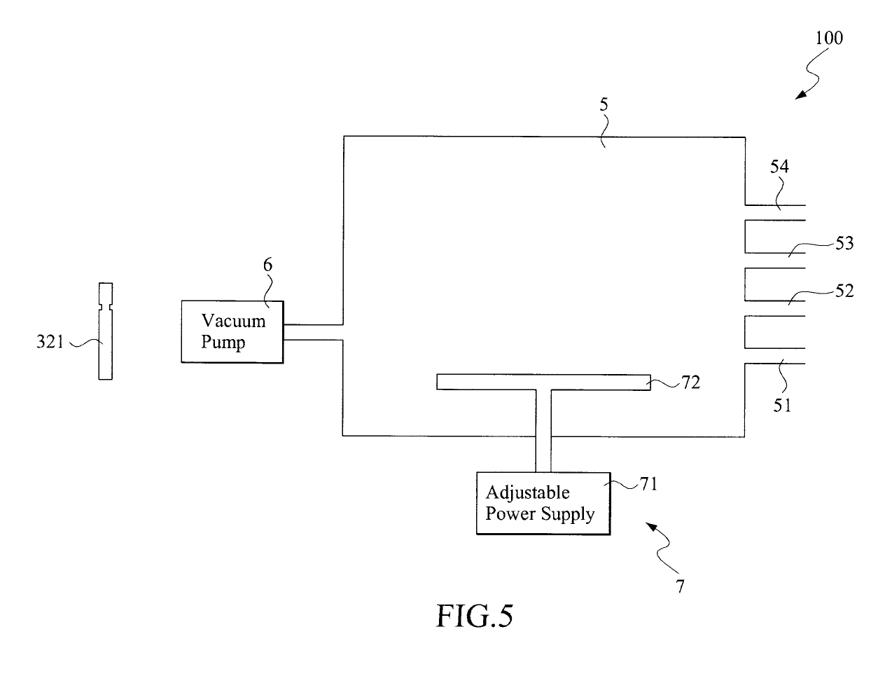

FIG. 5 illustrates a plasma enhanced chemical vapor deposition apparatus 100 for plating films on the main axle 321 according to the method of the present invention, thereby forming the driven shaft 32 shown in FIG. 4. The apparatus 100 includes a working chamber 5, a vacuum pump 6 for pumping out air from the chamber 5, a power control device 7. The chamber 5 is formed with four vents 51,52,53,54. The power control device 7 includes an adjustable power supply 71 disposed exterior of the chamber 5, a conductive carrier frame 72 extending into the chamber 5 from the power supply 71.

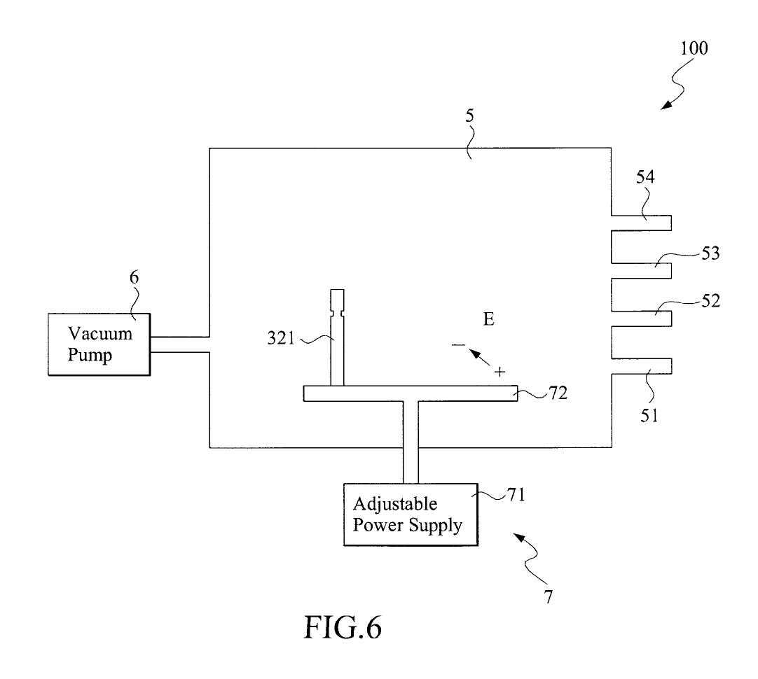

FIGS. 6 to 12 illustrates one embodiment of the film-plating method of the present invention. Firstly, the main axle 321 is erected securely on the carrier frame 72 as shown in FIG. 6 and is connected electrically to the power supply 71. An electric current is applied so as to generate a bias electric field within the chamber 5.

The pump 6 is activated to pump out the air from the working chamber 5, thereby converting into a vacuum chamber. The power supply 71 supplies an external electric current to the carrier frame 72 so that a high current level is existed in the frame 72 while a lower current level is existed in the chamber, thereby forming the bias electric field E.

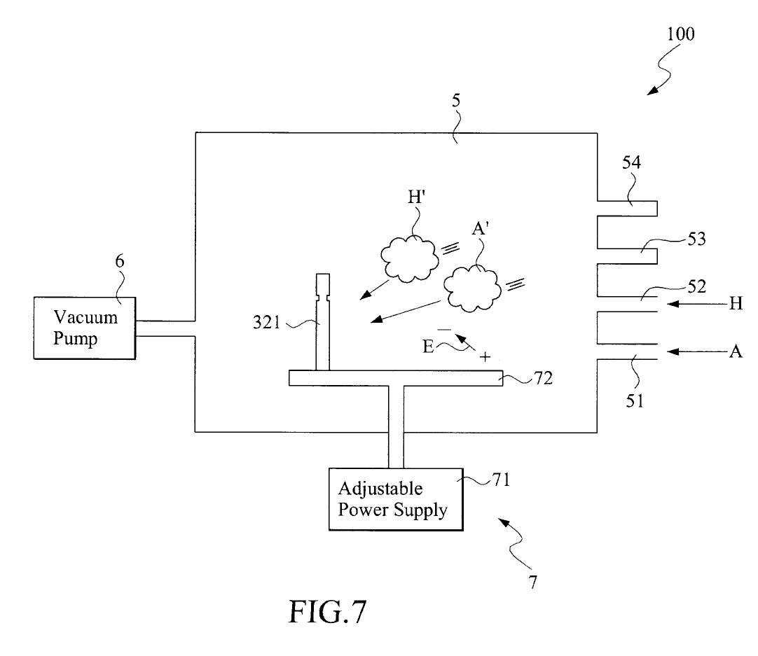

Referring to FIG. 7, gases are injected into the bias electric field in the vacuum chamber, where the gases become plasma-like ions after ionization process. In this embodiment, when plating a film on the main axle 321, H (hydrogen) and A (argon) gases are injected into the chamber 5 via the vents 51, 52 after shutting the vents 53, 54, wherein the gases convert into hydrogen ions H′ and argon ions A′ due to the bias electric field. The hydrogen and argon ions thus formed will collide against the main axle 321, thereby cleaning the external surface thereof.

The cleaning operation of the main axle 321 includes a first cleaning section of 10-25 minutes and a second cleaning section of 10-30 minutes. During the first cleaning section, the pressure in the vacuum chamber is maintained under 4-15μ bar, the bias electric field at 300-700V (Voltage) and the power of the applied electric current at 600-1400 W (watt), respectively. At the same, the flow rate of argon and hydrogen is maintained at 50-200 sccm (standard cc/min) respectively.

During the second cleaning time, the pressure in the working chamber is maintained under of 2-15μ bar, the bias electric field at 500-700V and the power of the applied electric current at 1200-1400 W. During this time, the flow rate of H is at 50-400 sccm while the flow rate of A is at 200-400 sccm (standard cc/min).

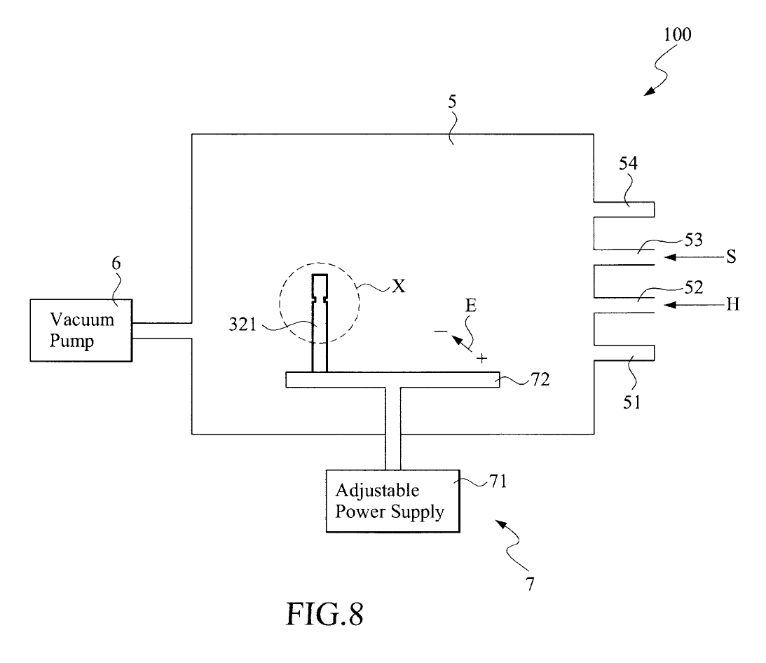

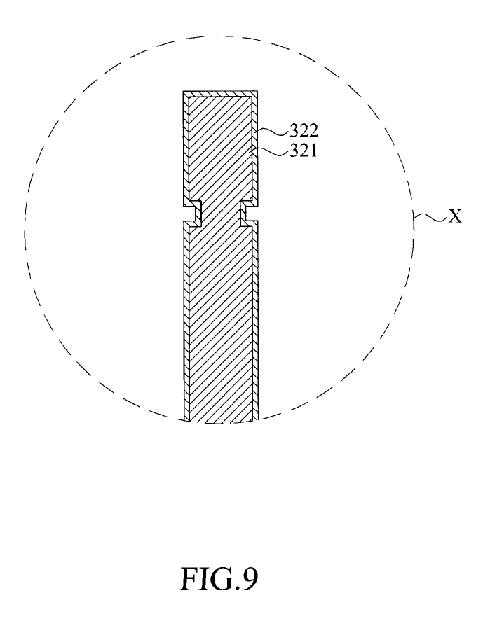

FIG. 8 shows an adherent film 322 being plated on the main axle 321 of the transmission mechanism according to the method of the present invention. FIG. 9 is an enlarged view of the encircled portion (X) shown in FIG. 8. For forming the adherent film 322, the vents 51 and 54 are closed firstly and hydrogen and tetra-methylsilane [TMS;Si(CH₃)₄] gases are injected into the working chamber 5 via the vents 52 and 53, wherein the adherent film 322 is deposited on the main axle 321 due to the bias electric field and after the ionization process.

For forming the adherent film 322, the flow rate of the hydrogen is maintained at 50-100 sccm while the TMS gas at 50-250 sccm for 1-10 min respectively. The adherent film 322 thus formed consists of Silicon, carborundum (SiC) and a minor portion of hydrocarbon compound. The adherent film 322 has a silicon ratio greater than the noncrystalline DLC material, and therefore adheres securely on the main axle 321. At this time, the power of the applied electric current is maintained at 800-1500 W while the bias electric field E at 400-700V and the working chamber is maintained under between 2-4μ bar.

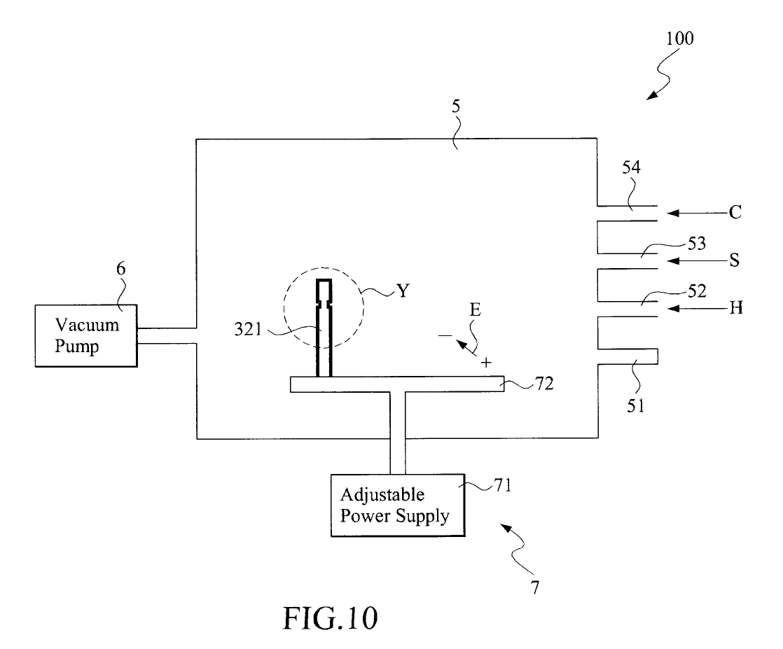

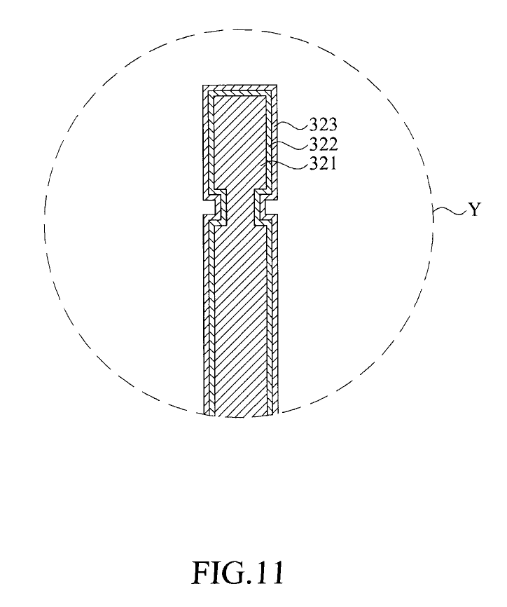

FIG. 10 illustrates how a mixed film being plated on the adherent film on the driven shaft of the transmission mechanism according to the method of the present invention. FIG. 11 is an enlarged view of the encircled portion (Y) shown in FIG. 10. In order to form a mixed film 323 over the adherent film 322, the vent 51 is closed firstly, and afterwards, hydrocarbon gas together with the hydrogen and tetra-methylsilane gases are injected into the working chamber via the vents 52, 53 and 54, thereby depositing the mixed film 323 over the adherent film 322 due to the ionization process caused by the bias electric field E. The hydrocarbon gas in this embodiment is Acetylene gas C.

It takes 1-10 min for depositing the mixed film 323 over the adherent film 322. During this period, the flow rate of Acetylene gas C is maintained at 50-800 sccm, the flow rate of hydrogen is maintained at 50-800 sccm while the flow the TMS gas S is maintained at 50-250 sccm. The applied electric current supplied by the power supply 71 is maintained at 800-1500 W so as to generate the bias electric field with 400-700 V. The working chamber is maintained between 2-4μ bar. The mixed film 323 thus formed consists of carborundum (SiC), noncrystalline DLC (diamond-like carbon) material and a minor portion of silicon. Since mixed film 323 has composition (such as Si and SiC) of the adherent film 322, the material of the mixed film 323 at the initial forming stage is similar to that of the adherent film 322 so that the mixed film 323 can be securely adhered on the adherent film 322.

During deposition of the mixed film 323, by slightly increasing the flow rate of Acetylene gas C, hydrogen and tetra-methylsilane gases, the mixed film 323 thus formed accordingly has the following features. The mixed film 323 has a distal portion that is spaced farthermost from the main axle 321 and that contains larger noncrystalline DLC (diamond-like carbon) material when compared to the remaining portion of the mixed film 323 and a proximate portion that contains composition similar to the adherent film 322.

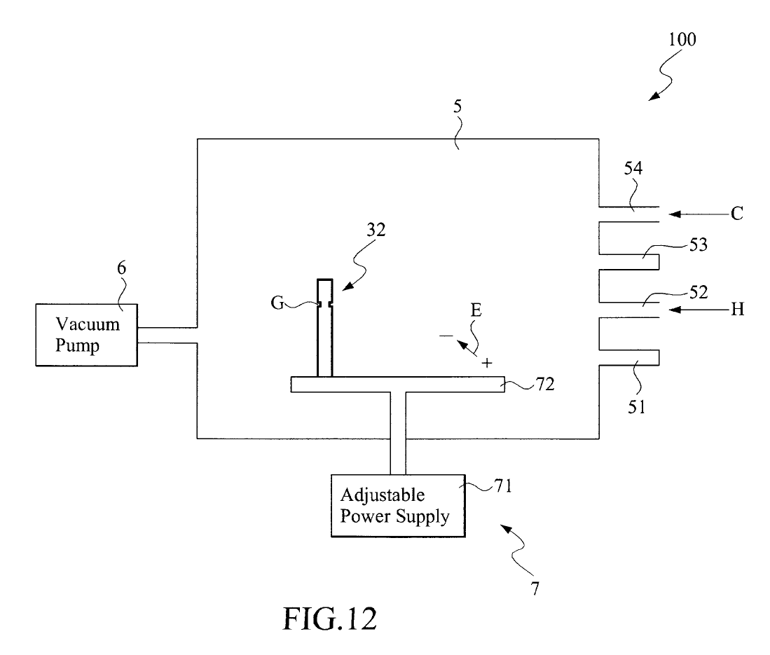

FIG. 12 illustrates how a noncrystalline DLC film being plated over the mixed film 323 according to the method of the present invention. For forming the noncrystalline DLC film 324 (see FIG. 4), the vent 51 in shut up immediately, the vent 52 is gradually shut up while the vents 52, 54 are open to inject the H and Acetylene gases into the working chamber 5. By ionization process due to the bias electric field E, the noncrystalline DLC film 324 is deposited over the mixed film 323, thereby completing plating of the driven shaft 32.

It takes 1-10 min for depositing the noncrystalline DLC film 324 over the mixed film 323. During this period, the flow rate of hydrogen and Acetylene is maintained at 50-800 sccm while the flow the TMS gas S is reduced gradually to 0 sccm. The applied electric current supplied by the power supply 71 is maintained at 800-1500 W so as to generate the bias electric field E with 400-700V. The working chamber is maintained between 10-20μ bar.

The outermost part of the mixed film 323 has the composition very similar to the noncrystalline DLC film 324. Thus, the noncrystalline DLC film 324 can tightly adhered on the mixed film 323. At the same time, since the mixed film 323 is tightly adhered on the adherent film 322, which, in turn, is tightly adhered on the main axle 321, the plated driven shaft 32 has the noncrystalline DLC film 324 tightly attached thereon.

From the above mentioned explanation, it is apparent for those skilled in the art that the plated transmission mechanism of the present invention includes the noncrystalline DLC film with better adhesive ability to prevent from dropping off the main axle when compared to the prior art ones.

When compare to the prior art plating method, when conducting the present method, it is required to raise the temperature about 80° C. during the first and second cleaning sections. Under this temperature, there will be no thermal cycling effect for the main axle 321.

During forming of the adherent film 322, the mixed film 323 and the noncrystalline DLC film 324, the vent 51 in the working chamber 5 is constantly kept closed. The reason resides in that the electric current supplied by the power supply 71 is always maintained at the high power of 800-1500 W. No argon gas is required to be injected into the working chamber to form the plasma-like status. Therefore, the problem of rupturing the bonding ability due to present of the argon compound can be avoided.

From the abovementioned explanation, some of the reference parameters are altered in the film-plating method of the present invention to avoid the problems of thermal cycling effect, rupturing the bonding ability due to present of the argon in the noncrystalline DLC film. Thus, the noncrystalline DLC film formed accordingly has enhanced adhesive ability and increases the hardness of the external surface of the plated transmission mechanism. Since the noncrystalline DLC film having enhanced adhesive ability and the plated transmission mechanism possessing high hardness at the external surface, the wear-resistant properties and the service life thereof are also increased.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method for plating film on the external surface of a transmission mechanism comprising the steps of:
(a) preparing the transmission mechanism;
(b) cleaning the external surface of the transmission mechanism;
(c) disposing the transmission mechanism into a working chamber, injecting hydrogen and tetra-methylsilane [TMS; Si(CH₃)₄] gases therein and applying an electric current with a power of 800-1500 watt to generate a bias electric field within the working chamber, thereby forming an adherent film on the external surface of the transmission mechanism, wherein the bias electric field is maintained at 400-700 V;
(d) injecting hydrocarbon gas together with the hydrogen and tetra-methylsilane gases into the working chamber while maintaining the bias electric field at 400-700 V and the applied electric current at 800-1500 watt, thereby forming a mixed film on an external surface of the adherent film, wherein the mixed film consisting of noncrystalline DLC (diamond-like carbon) material and composition of the adherent film, the mixed film having a distal portion that is spaced farthermost from the transmission mechanism and that consists of larger noncrystalline DLC (diamond-like carbon) material when compared to the remaining portion of the mixed film; and
(e) injecting the hydrogen and tetra-methylsilane gases together with hydrocarbon gas into the working chamber while maintaining the bias electric field at 400-700 V and the applied electric current at 800-1500 watt, thereby forming a noncrystalline DLC film on the mixed film.

2. The method for plating films according to claim 1, wherein the step (b) further includes the following substeps of:
(b1) disposing the transmission mechanism into the working chamber;
(b2) applying the electric current to generate the bias electric field within the working chamber;
(b3) injecting at least one gas into the working chamber; and
(b4) utilizing the bias electric field to convert the gas into a plasma-like substance so as to clean the external surface of the transmission mechanism.

3. The method for plating films according to claim 2, wherein the step (b) further includes the following substeps of:
cleaning for a first cleaning section of 10-25 min while the working chamber is maintained under pressure of 4-15μ bar, the bias electric field at 300-700V and the power of the applied electric current at 600-1400 W.

4. The method for plating films according claim 3, wherein during the first cleaning section, the gas in the working chamber consists of argon and hydrogen, the argon and hydrogen having a flow rate of 50-200 sccm (standard cc/min) respectively and the combined gas being converted into plasma-like argon ions and plasma-like hydrogen ions after ionization process.

5. The method for plating films according to claim 2, wherein the step (b) further includes the following substeps of:
cleaning for a second cleaning section of 10-30 min while the working chamber is maintained under pressure of 2-15μ bar, the bias electric field at 300-700V and the power of the applied electric current at 1200-1400 W.

6. The method for plating films according to claim 5, wherein during the second cleaning section, the gas in the working chamber consists of argon and hydrogen, the argon having a flow rate of 200-400 sccm (standard cc/min) and the hydrogen 50-400 sccm, the combined gas being converted into plasma-like argon ions and plasma-like hydrogen ions after ionization process.

7. The method for plating films according to claim 1, wherein an adjustable power source supplier is used for supplying the external electric current.

8. The method for plating films according to claim 1, wherein during the step (c), flow rate of the hydrogen is maintained at 50-100 sccm while the TMS gas at 50-250 sccm for 1-10 min respectively.

9. The method for plating films according to claim 1, wherein during the step (c), the working chamber is maintained under pressure of 2-4μ bar.

10. The method for plating films according to claim 1, wherein during the step (d), flow rate of the hydrogen is maintained at 50-800 sccm and the TMS gas at 50-250 sccm for 1-10 min respectively, the hydrocarbon gas being acetylene having a flow maintained at 50-800 sccm.

11. The method for plating films according to claim 1, wherein during the step (d), the working chamber is maintained under pressure of 4-15μ bar.

12. The method for plating films according to claim 1, wherein during the step (e), flow rate of the hydrogen is maintained at 50-800 sccm while flow the TMS gas is lowered gradually to 0 sccm for 1-10 min respectively, the hydrocarbon gas being acetylene having a flow maintained at 50-800 sccm.

13. The method for plating films according to claim 1, wherein during the step (e), the working chamber is maintained under pressure of 10-20μ bar.

14. The method for plating films according to claim 1, wherein the adherent film consists of carborundum (SiC), the mixed film consisting of noncrystalline DLC material and silicon carbide.

15. The method for plating films according to claim 1, wherein the transmission mechanism includes a bearing unit, a drive shaft, a chain, a gear wheel, a rack, a cam member, a bevel shaft or a combination thereof.
